(19) United States
(12) Patent Application Publication
(10) Pub. No.: US 2016/0021780 A1
(43) Pub. Date: Jan. 21, 2016

(54) Carrier, Semiconductor Module and Fabrication Method Thereof

(71) Applicant: Infineon Technologies AG, Neubiberg (DE)

(72) Inventor: Alexander Schwarz, Soest (DE)

(21) Appl. No.: 14/797,304

(22) Filed: Jul. 13, 2015

(30) Foreign Application Priority Data
Jul. 16, 2014 (DE) 102014110008.5

(51) Int. Cl. H05K 7/20; H05K 1/09; H05K 1/03; H05K 1/02; H05K 1/18; H05K 3/30

(52) U.S. Cl. CPC H05K 7/205; H05K 1/181; H05K 3/303; H05K 1/0306; H05K 1/0204; H05K 1/09; H05K 2201/09009; H05K 2201/066

(57) ABSTRACT

A semiconductor module includes a carrier having a first carrier surface and a second carrier surface opposite the first carrier surface, a first semiconductor chip mounted over the first carrier surface and a heatsink coupled to the second carrier surface with a first heatsink surface facing the carrier. The second carrier surface or the first heatsink surface has at least one cavity in the form of one or more of dimples and trenches.

### PRIORITY CLAIM

This application claims priority to German Patent Application No. 10 2014 110008.5 filed on 16 Jul. 2014, the content of said application incorporated herein by reference in its entirety.

### TECHNICAL FIELD

The disclosure relates to carriers, semiconductor modules and to methods for fabricating these.

### BACKGROUND

A semiconductor module may produce a significant amount of heat during operation, for example in a semiconductor chip or in electrical connections carrying a high current density. The heat generated may necessitate the inclusion of a heatsink in the semiconductor device, wherein the heatsink may absorb the generated heat. It may be desirable to ensure an optimum thermal connection between the heatsink and those active parts of the semiconductor module which produce heat. Providing an optimum thermal connection may comprise providing a thermal grease layer between the heatsink and the active parts, wherein the thermal grease layer has an optimum thickness.

### SUMMARY

According to an embodiment of a carrier, the carrier comprises a first surface comprising at least a first semiconductor chip bearing area and a second surface opposite the first surface and comprising at least one cavity in the form of one or more of dimples and trenches.

According to an embodiment of a semiconductor module, the semiconductor module comprises a carrier comprising a first carrier surface and a second carrier surface opposite the first carrier surface, a first semiconductor chip mounted over the first carrier surface and a heatsink coupled to the second carrier surface with a first heatsink surface facing the carrier. The second carrier surface or the first heatsink surface comprises at least one cavity in the form of one or more of dimples and trenches.

According to an embodiment of a method for fabricating a semiconductor module, the method comprises: providing a carrier comprising a first carrier surface and a second carrier surface opposite the first carrier surface; mounting a first semiconductor chip over the first carrier surface; and coupling a heatsink to the second carrier surface such that a first heatsink surface faces the second carrier surface. The second carrier surface or the first heatsink surface comprises at least one cavity in the form of one or more of dimples and trenches.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference numerals may designate corresponding similar parts.

FIG. 1 shows a topside of a carrier comprising a semiconductor chip bearing area.

FIG. 2A shows a backside of the carrier of FIG. 1.

FIG. 2B shows the backside of a carrier comprising a surface structuring in the form of several trenches.

FIG. 2C shows a cross-sectional view of the carrier of FIG. 2B along line A-A′.

FIG. 3A shows a backside of a further example of a carrier. The carrier backside of FIG. 3A comprises a surface structuring in the form of several dimples.

FIG. 3B shows a cross-sectional view of the carrier of FIG. 3A along line B-B′.

FIG. 4A shows a backside of a further example of a carrier. The backside of the carrier of FIG. 4A comprises a surface structuring in the form of both trenches and dimples.

FIG. 4B shows a backside of a further example of a carrier. The backside of the carrier of FIG. 4B comprises dimples.

FIG. 5A shows a side view of an example of a semiconductor module.

FIG. 5B shows a side view of a further example of a semiconductor module.

FIG. 6 shows a side view of a further example of a semiconductor module. The semiconductor module of FIG. 6 comprises a heatsink comprising a surface structuring on a first heatsink surface, wherein the first heatsink surface faces a carrier of the semiconductor module.

FIG. 7 shows a side view of a further example of a semiconductor module. The semiconductor module of FIG. 7 comprises a base plate.

FIG. 8 shows a side view of a Direct Copper Bond substrate.

FIG. 9 shows a flow diagram of a method for fabricating a semiconductor module.

### DETAILED DESCRIPTION

In the following detailed description, reference is made to the accompanying drawings which illustrate specific aspects in which the disclosure may be practiced. In this regard, directional terminology, such as “top”, “bottom”, “front”, “back”, etc., may be used with reference to the orientation of the figures being described. Since components of described devices may be positioned in a number of different orientations, the directional terminology may be used for purposes of illustration and is in no way limiting.

The various aspects summarized may be embodied in various forms. The following description shows by way of illustration various combinations and configurations in which the aspects may be practiced. It is understood that the described aspects and/or examples are merely examples and that other aspects and/or examples may be utilized and structural and functional modifications may be made without departing from the scope of the present disclosure. The following detailed description is therefore not to be taken in a limiting sense, and the scope of the present disclosure is defined by the appended claims. In addition, while a particular feature or aspect of an example may be disclosed with respect to only one of several implementations, such feature or aspect may be combined with one or more other features or aspects of the other implementations as it may be desired and advantageous for any given or particular application.

It is to be appreciated that features and/or elements depicted herein may be illustrated with particular dimensions relative to each other for purposes of simplicity and ease of understanding. Actual dimensions of the features and/or elements may differ from that illustrated herein.

As employed in this specification, the terms “connected”, “coupled”, “electrically connected” and/or “electrically coupled” are not meant to mean that the elements must be directly coupled together. Intervening elements may be provided between the “connected”, “coupled”, “electrically connected” and/or “electrically coupled” elements.

The words “over” and “on” used with regard to e.g. a material layer formed or located “over” or “on” a surface of an object may be used herein to mean that the material layer may be located (e.g. formed, deposited, etc.) “directly on”, e.g. in direct contact with, the implied surface. The words “over” and “on” used with regard to e.g. a material layer formed or located “over” or “on” a surface may also be used herein to mean that the material layer may be located (e.g. formed, deposited, etc.) “indirectly on” the implied surface with e.g. one or more additional layers being arranged between the implied surface and the material layer.

To the extent that the terms “include”, “have”, “with” or other variants thereof are used in either the detailed description or the claims, such terms are intended to be inclusive in a manner similar to the term “comprise”. Also, the term “exemplary” is merely meant as an example, rather than the best or optimal.

Semiconductor modules, carriers and methods for manufacturing the semiconductor modules and carriers are described herein. Comments made in connection with a described semiconductor module or carrier may also hold true for a corresponding method and vice versa. For example, when a specific component of a semiconductor module or carrier is described, a corresponding method for manufacturing the semiconductor module or carrier may include an act of providing the component in a suitable manner, even when such act is not explicitly described or illustrated in the figures. A sequential order of acts of a described method may be exchanged if technically possible. At least two acts of a method may be performed at least partly at the same time. In general, the features of the various exemplary aspects described herein may be combined with each other, unless specifically noted otherwise.

Semiconductor modules in accordance with the disclosure may include one or more semiconductor chips. The semiconductor chips may be of different types and may be manufactured by different technologies. For example, the semiconductor chips may include integrated electrical, electro-optical or electro-mechanical circuits or passives. The integrated circuits may be designed as logic integrated circuits, analog integrated circuits, mixed signal integrated circuits, power integrated circuits, memory circuits, integrated passives, micro-electro mechanical systems, etc. The semiconductor chips may be manufactured from any appropriate semiconductor material, for example at least one of Si, SiC, SiGe, GaAs, GaN, etc. Furthermore, the semiconductor chips may contain inorganic and/or organic materials that are not semiconductors, for example at least one of insulators, plastics, metals, etc. The semiconductor chips may be packaged or unpackaged.

In particular, one or more of the semiconductor chips may include a power semiconductor. Power semiconductor chips may have a vertical structure, i.e. the semiconductor chips may be fabricated such that electric currents may flow in a direction perpendicular to the main faces of the semiconductor chips. A semiconductor chip having a vertical structure may have electrodes on its two main faces, i.e. on its top side and bottom side. In particular, power semiconductor chips may have a vertical structure and may have load electrodes on both main faces. For example, the vertical power semiconductor chips may be configured as power MOSFETs (Metal Oxide Semiconductor Field Effect Transistors), IGBTs (Insulated Gate Bipolar Transistors), JFETs (Junction Gate Field Effect Transistors), super junction devices, power bipolar transistors, etc. The source electrode and gate electrode of a power MOSFET may be situated on one face, while the drain electrode of the power MOSFET may be arranged on the other face. In addition, the devices described herein may include integrated circuits to control the integrated circuits of the power semiconductor chips.

The semiconductor chips may include contact pads (or contact terminals) which may allow electrical contact to be made with integrated circuits included in the semiconductor chips. For the case of a power semiconductor chip, a contact pad may correspond to a gate electrode, a source electrode or a drain electrode. The contact pads may include one or more metal and/or metal alloy layers that may be applied to the semiconductor material. The metal layers may be manufactured with any desired geometric shape and any desired material composition.

Semiconductor modules in accordance with the disclosure may include a carrier or substrate. The carrier may be configured to provide electrical interconnections between electronic components and/or semiconductor chips arranged over the carrier such that an electronic circuit may be formed. In this regard, the carrier may act similar to a Printed Circuit Board (PCB). The materials of the carrier may be chosen to support a cooling of electronic components arranged over the carrier. The carrier may be configured to carry high currents and provide high voltage isolation, for example up to several thousand volts. The carrier may further be configured to operate at temperatures up to 150° C., in particular up to 200° C. or even higher. Since the carrier may particularly be employed in power electronics, it may also be referred to as “power electronic substrate” or “power electronic carrier”.

The carrier may include an electrically insulating core that may include at least one of a ceramic material and a plastic material. For example, the electrically insulating core may include at least one of aluminum oxide, aluminum nitride, beryllium oxide, etc. The carrier may have one or more main surfaces, wherein at least one main surface may be formed such that one or more semiconductor chips may be arranged thereupon. In particular, the substrate may include a first main surface and a second main surface arranged opposite to the first main surface. The first main surface and the second main surface may be substantially parallel to each other. The electrically insulating core may have a thickness between about 50 μm (micrometer) and about 1.6 millimeter.

Semiconductor modules in accordance with the disclosure may include a first electrically conductive material that may be arranged over (or on) a first main surface of the carrier. In addition, the semiconductor module may include a second electrically conductive material that may be arranged over (or on) a second main surface of the carrier opposite to the first main surface. The term “carrier” as used herein may refer to the electrically insulating core, but may also refer to the electrically insulating core including the electrically conductive material arranged over the core. The electrically conductive material may include at least one of a metal and a metal alloy, for example copper and/or a copper alloy. The electrically conductive material may be shaped or structured in order to provide electrical interconnections between electronic components arranged over the carrier. In this regard, the electrically conductive material may include electrically conductive lines, layers, surfaces, zones, etc. For example, the electrically conductive material may have a thickness between about 0.1 millimeter and about 0.5 millimeter.

In one example, the carrier may correspond to (or may include) a Direct Copper Bond (DCB) or Direct Bond Copper (DBC) substrate. A DCB substrate may include a ceramic core and a sheet or layer of copper arranged over (or on) one or both main surfaces of the ceramic core. The ceramic material may include at least one of alumina (Al₂O₃), that may have a thermal conductivity from about 24 W/mK to about 28 W/mK, aluminum nitride (AlN), that may have a thermal conductivity greater than about 150 W/mK, beryllium oxide (BeO), etc. Compared to pure copper, the carrier may have a coefficient of thermal expansion similar or equal to that of silicon.

For example, the copper may be bonded to the ceramic material using a high-temperature oxidation process. Here, the copper and the ceramic core may be heated to a controlled temperature in an atmosphere of nitrogen containing about 30 ppm of oxygen. Under these conditions, a copper-oxygen eutectic may form which may bond both to copper and oxides that may be used as substrate core. The copper layers arranged over the ceramic core may be pre-formed prior to firing or may be chemically etched using a printed circuit board technology to form an electrical circuit. A related technique may employ a seed layer, photo imaging and additional copper plating in order to allow for electrically conductive lines and through-vias to connect a front main surface and a back main surface of the substrate.

In a further example, the carrier may correspond to (or may include) an Active Metal Brazed (AMB) substrate. In AMB technology, metal layers may be attached to ceramic plates. In particular, a metal foil may be soldered to a ceramic core using a solder paste at high temperatures from about 800° C. to about 1000° C.

In yet a further example, the carrier may correspond to (or may include) an Insulated Metal Substrate (IMS). An IMS may include a metal base plate covered by a thin layer of dielectric and a layer of copper. For example, the metal base plate may be made of or may include at least one of aluminum and copper while the dielectric may be an epoxy-based layer. The copper layer may have a thickness from about 35 μm (micrometer) to about 200 μm (micrometer) or even higher. The dielectric may e.g. be FR-4-based and may have a thickness of about 100 μm (micrometer).

Semiconductor modules in accordance with the disclosure may include an encapsulation material that may cover one or more components of the module. For example, the encapsulation material may at least partly encapsulate the carrier. The encapsulation material may be electrically insulating and may form an encapsulation body or encapsulant. The encapsulation material may include a thermoset, a thermoplastic or hybrid material, a mold compound, a laminate (prepreg), a silicone gel, etc. Various techniques may be used to encapsulate the components with the encapsulation material, for example at least one of compression molding, injection molding, powder molding, liquid molding, lamination, etc.

Semiconductor modules in accordance with the disclosure may include one or more electrically conductive elements. In one example, an electrically conductive element may provide an electrical connection to a semiconductor chip of the device. For example, the electrically conductive element may be connected to an encapsulated semiconductor chip and may protrude out of the encapsulation material. Hence, it may be possible to electrically contact the encapsulated semiconductor chip from outside of the encapsulation material via the electrically conductive element. In a further example, an electrically conductive element may provide an electrical connection between components of the device, for example between two semiconductor chips. A contact between the electrically conductive element and e.g. a contact pad of a semiconductor chip may be established by any appropriate technique. In an example, the electrically conductive element may be soldered to another component, for example by employing a diffusion soldering process.

In one example, the electrically conductive element may include one or more clips (or contact clips). The shape of a clip is not necessarily limited to a specific size or a specific geometric shape. The clip may be fabricated by at least one of stamping, punching, pressing, cutting, sawing, milling, and any other appropriate technique. For example, it may be fabricated from metals and/or metal alloys, in particular at least one of copper, copper alloys, nickel, iron nickel, aluminum, aluminum alloys, steel, stainless steel, etc. In a further example, the electrically conductive element may include one or more wires (or bond wires or bonding wires). The wire may include a metal or a metal alloy, in particular gold, aluminum, copper, or one or more of their alloys. In addition, the wire may or may not include a coating. The wire may have a thickness from about 15 μm (micrometer) to about 1000 μm (micrometer), and more particular a thickness of about 50 μm (micrometer) to about 500 μm (micrometer).

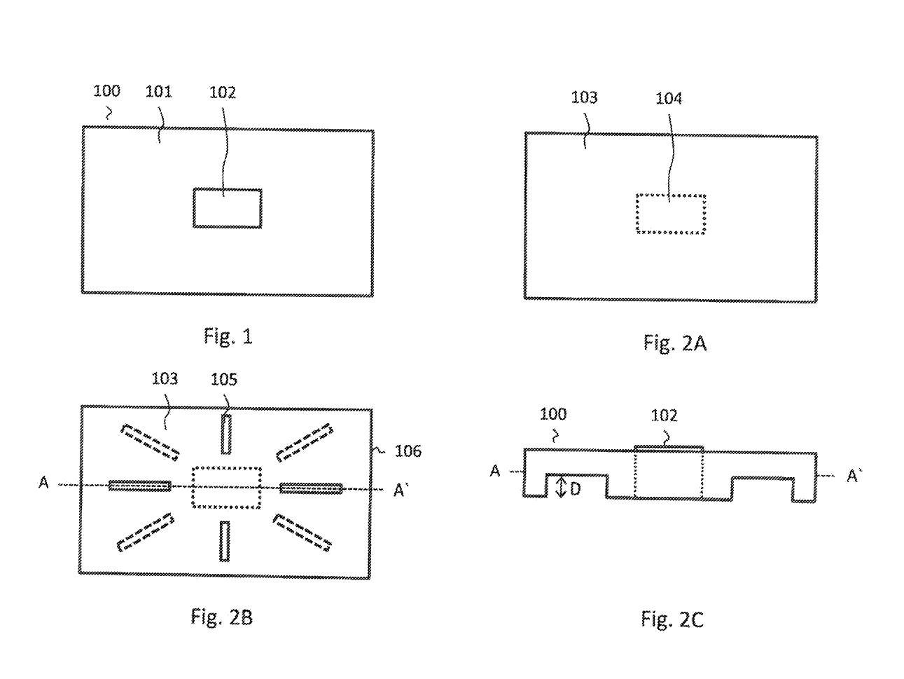

In FIG. 1 a carrier 100 in accordance with the disclosure is shown in top view. Carrier 100 may comprise a first main surface 101, which may also be called the topside of the carrier 100. Located on the topside 101 may be at least a first chip bearing area 102 configured to be coupled to a first semiconductor chip (not shown). Carrier topside 101 may be structured and may in particular comprise electrical connections not shown in FIG. 1. The chip bearing area 102 is not required to be located in the center of topside 101 as shown in FIG. 1, but may also be located at any desirable position on topside 101.

Carrier 100 may exhibit a rectangular shape. A first edge of a rectangular carrier may be for example about 42 cm long, but may also be shorter than 42 cm, in particular shorter than 30 cm, shorter than 20 cm, shorter than 10 cm, or even shorter than 5 cm. The first edge may also be longer than 42 cm, even longer than 50 cm and even longer than 60 cm. A second edge of a rectangular carrier may be about 32 cm long, but may also be shorter than 32 cm, shorter than 20 cm, shorter than 10 cm, and even shorter than 5 cm. The second edge may also be longer than 32 cm, longer than 40 cm, and even longer than 50 cm. Furthermore, carriers in accordance with the disclosure like carrier 100 need not necessarily be of rectangular shape as shown in FIG. 1, but may rather have any other desirable shape in further examples.

Carrier 100 may comprise one or more further chip bearing areas apart from the first chip bearing area 102. The one or more further chip bearing areas may also be located on topside 101. The individual chip bearing areas may have distinct sizes and shapes and may be configured to be coupled to different kinds of semiconductor chips.

FIG. 2A shows a second main surface 103 of carrier 100 (which may also be termed the backside of carrier 100). The rectangle 104 illustrated with a dashed line represents the outline of the chip bearing area 102 located on the topside 101.

In order to fabricate a semiconductor module comprising carrier 100, carrier 100 may be configured to be coupled to a further structural element such that backside 103 may face the further structural element. As will be shown below, the further structural element may for example comprise a heatsink. The heatsink may be configured to absorb and dissipate heat. Such heat may be generated by one or more semiconductor chips coupled to one or more chip bearing areas of carrier 100. As shown in more detail further below, a thermal grease may be applied between the backside 103 of carrier 100 and the heatsink in order to improve a heat transfer between carrier 100 and the heatsink. A mechanical fixing means may be used to couple the heatsink to the carrier. The mechanical fixing means may for example comprise one or more clamps and/or one or more screws and/or one or more springs.

The mechanical fixing means may apply pressure onto the carrier, the heatsink and the thermal grease located between the carrier and the heatsink. The thermal grease may form a thermal grease layer between the carrier and the heatsink. A thickness of the thermal grease layer may depend on the amount of pressure exerted onto the carrier and the heatsink with higher pressure resulting in a thinner thermal grease layer. A thinner thermal grease layer may exhibit improved heat transfer properties compared to a thicker thermal grease layer. However, it may not be feasible to increase the pressure beyond a certain point because this may result in mechanically damaging some parts like, for example, the carrier. Therefore, it may be beneficial to somehow reduce the thickness of the thermal grease layer as much as possible without increasing the pressure.

FIG. 2B shows backside 103 after a surface structuring process has been applied to it. In particular, FIG. 2B shows backside 103 comprising cavities in the form of trenches 105. Trenches 105 may have any desirable shape and size. In the example of FIG. 2B, trenches 105 may exhibit a rectangular shape. In further examples, trenches 105 may have any other suitable shape, for example a triangular shape, a curved shape, etc. Trenches 105 may have a width of about 1/20^{th} of a millimeter to about 5 mm, or may have a width of even more than 5 mm. Trenches 105 may have a length anywhere in the region of about 5 mm to about 30 cm depending on the particular carrier configuration. Trenches 105 may cover almost the whole backside 103, or they may cover only some part of it, for example less than ½ of backside 103, less than ¼ of backside 103, or even less than ⅛ of backside 103.

The area 104 on backside 103 corresponding to the chip bearing area 102 located on topside 101 may be free of any trenches 105. Furthermore, a border area directly adjacent to area 104 may be free of trenches 105. The border area may completely surround area 104. In other words, trenches 105 may be arranged at a certain distance from area 104. However, in some cases it maybe beneficial to have trenches 105 start directly at the outline of area 104.

Trenches 105 may be arranged in a radial pattern around area 104 as exemplarily shown in FIG. 2B by a combination of trenches illustrated by continuous lines and trenches illustrated by dashed lines. That is to say, trenches 105 may point away from area 104. It may be also possible to arrange trenches 105 in such a manner that trenches 105 may be arranged perpendicular to the outline of area 104 as shown in FIG. 2B by the trenches 105 illustrated by continuous lines.

Keeping area 104 (and possibly also a border area directly adjacent to area 104) free of any trenches may facilitate the transfer of heat, e.g. generated by a semiconductor chip that may be coupled to chip bearing area 102, to a heatsink that may be coupled to carrier backside 103. The distance between carrier 100 and the heatsink may be larger at locations over the trenches. Therefore, the thermal coupling between the carrier and the heatsink may be reduced at these locations and the trench may act as an increased thermal resistance. If a trench is located in area 104 (and/or in the border area), heat generated by a semiconductor chip coupled to chip bearing area 102 cannot be transferred to the heatsink as efficiently as in the case of no trenches being located in area 104 (and/or the border area directly adjacent to area 104).

Furthermore, by arranging trenches 105 in a radial pattern around area 104 or perpendicular to an outline of area 104, such that only a short side of rectangular trenches 105 faces area 104, heat may dissipate from area 104 to further parts of carrier 100 unobstructed or almost unobstructed.

When coupling carrier backside 103 to a heatsink such that a thermal grease is located between carrier backside 103 and the heatsink, trenches 105 may act as a reservoir for receiving or storing excess thermal grease. In other words, when pressing carrier 100 and the heatsink together, excess thermal grease may be pressed into the trenches, thereby reducing the thickness of the thermal grease layer between the carrier and the heatsink without having to increase the applied pressure. A reduced thermal grease layer thickness in turn may result in an improved thermal connection between the carrier and the heatsink.

Trenches 105 may for example be fabricated by etching and/or by laser ablation and/or by any other suitable surface structuring technique.

In FIG. 2C a side view of carrier 100 along line A-A′ of FIG. 2B is shown. Trenches 105 may have any suitable depth D. In one example, trenches 105 may have a depth D in the range of about 1/20^{th} of a millimeter to about 5 mm. Furthermore, in the case that carrier 100 comprises a stack of several layers of conductive material and/or insulating material, a trench of depth D may penetrate only a part of a first layer of the stack, a trench of depth D may penetrate the complete first layer, a trench of depth D may even penetrate partly or completely through a second layer of the stack, and a trench of depth D may even penetrate partly or completely through further layers of the stack. In particular, a trench of depth D may even penetrate the whole thickness of carrier 100. In other words, trenches 105 may be configured as slits through carrier 100 connecting the topside 101 with the backside 103. Furthermore, it may be possible to have individual trenches 105 of different depths on a single carrier 100.

Note that in the example of FIGS. 2B and 2C trenches 105 are shown to not reach an outline 106 of carrier 100. However, in further examples of a carrier 100, at least one of trenches 105 may be configured to cross the outline 106 of carrier 100.

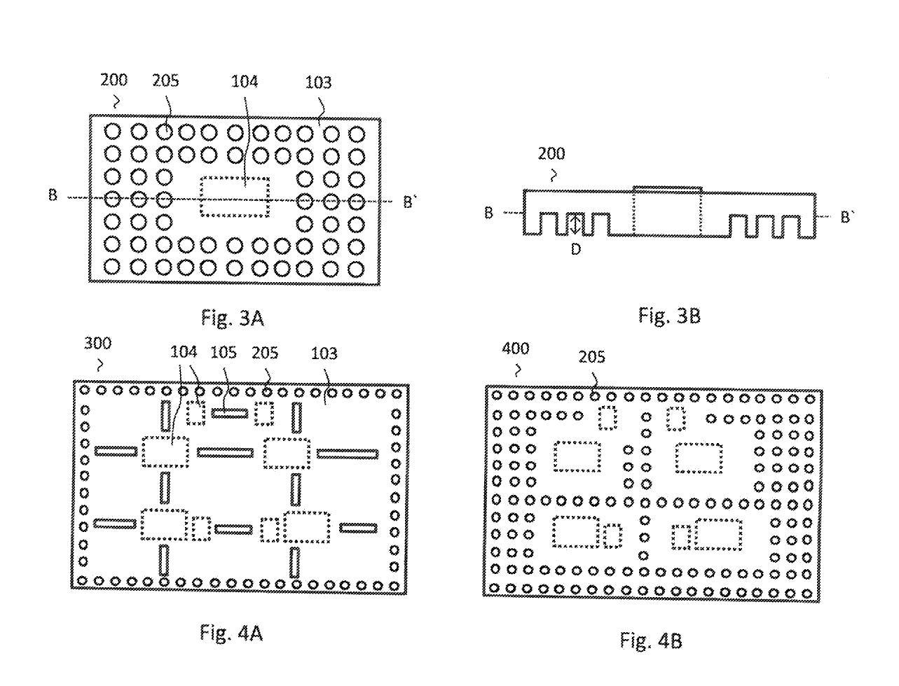

In FIG. 3A a backside 103 of a carrier 200 is shown. Carrier 200 may comprise similar parts as carrier 100 which may be labeled with identical reference signs. Comments made in connection with foregoing figures may also hold true for FIGS. 3A and 3B.

Instead of the trenches 105 of carrier 100, carrier 200 may comprise cavities in the form of dimples 205. Dimples 205 may serve the same purpose as trenches 105 described in connection with previous figures. In particular, dimples 205 may act as reservoirs for excess thermal grease, thereby allowing the fabrication of a particularly thin thermal grease layer at a given pressure as described above.

Dimples 205 may be arranged such that an area 104 beneath a chip bearing area remains free of any dimples. Furthermore, dimples 205 may be arranged such that a border area directly surrounding area 104 remains free of any dimples. Dimples 205 may be arranged in any suitable pattern on carrier backside 103 depending on the specific functionality and layout of the considered device. For example, dimples 205 may be arranged in rows and columns. Dimples 205 may cover almost the whole backside 103. In a further example, dimples 205 may cover only some part of backside 103, for example less than ½ of backside 103, less than ¼ of backside 103, or even less than ⅛ of backside 103.

In FIG. 3B a cross-sectional view of carrier 200 along line B-B′ is shown. Dimples 205 may have a diameter anywhere in the region of about 1/20^{th} of a millimeter to 1 cm or even more than 1 cm. Dimples 205 may have a depth D similar to depth D of trenches 105.

Dimples 205 may be fabricated using similar surface structuring techniques as described with respect to trenches 105, for example using techniques that comprise at least one of etching and laser ablation.

In one further example, it may be possible to have both dimples and trenches in a single carrier if such a surface structuring may be advantageous for the specific carrier configuration.

In FIG. 4A a backside 103 of a further carrier 300 is shown. Carrier 300 may be essentially identical to carriers 100 and 200. However, carrier 300 may comprise several chip bearing areas 102 on its topside. Consequently, the outlines of the several areas 104 located directly below these several chip bearing areas 102 are shown in FIG. 4A. The several chip bearing areas may be configured to be all coupled to the same type of semiconductor chip, or to different types of semiconductor chips. For example, power semiconductor chips and/or integrated circuit chips may be coupled to carrier 300.

Backside 103 of carrier 300 may comprise trenches 105. Trenches 105 may be arranged as described with respect to carrier 100 of FIG. 2B. In particular, trenches 105 may be arranged basically perpendicular or in a radial pattern with respect to areas 104. Backside 103 may comprise trenches 105 but no dimples or it may comprise both trenches 105 and dimples 205. Dimples 205 may for example be arranged along an outline of carrier backside 103 as shown in FIG. 4A or they may be arranged on backside 103 in any other suitable pattern.

FIG. 4B shows a backside 103 of a further carrier 400. Carrier 400 may be identical to carrier 300 except for the fact that carrier 400 does not comprise trenches 105 on its backside 103 but only dimples 205. Using dimples instead of trenches as reservoirs for excess thermal grease may be advantageous in some cases. For example, a stacked substrate like a DCB substrate comprising only dimples but no trenches may exhibit a stronger coupling between a backside metal layer comprising the dimples instead of trenches and a core ceramics layer.

Carriers like carriers 100, 200, 300 and 400 may comprise electrical connections (not shown in the Figures). Such electrical connections may for example be configured to connect to a semiconductor chip that may be coupled to a chip bearing area 102. For example, in the case that a high current density flows through such electrical connections, such electrical connections may heat up. Therefore, an area of the backside of a carrier 100, 200, 300 or 400 located directly below such an electrical connection may be kept free of any trenches 105 and/or dimples 205 in order to allow for an unobstructed heat flow from the electrical connection to a heatsink coupled to the backside of the carrier. In other words, carriers comprising trenches 105 or dimples 205 on their backsides, like carriers 100, 200, 300 and 400, may comprise areas like areas 104 which are kept free of any trenches or dimples. These areas may be located below any kind of “thermal hotspot” of the carrier in order to ensure an unobstructed heat transfer from the thermal hotspot to a heatsink.

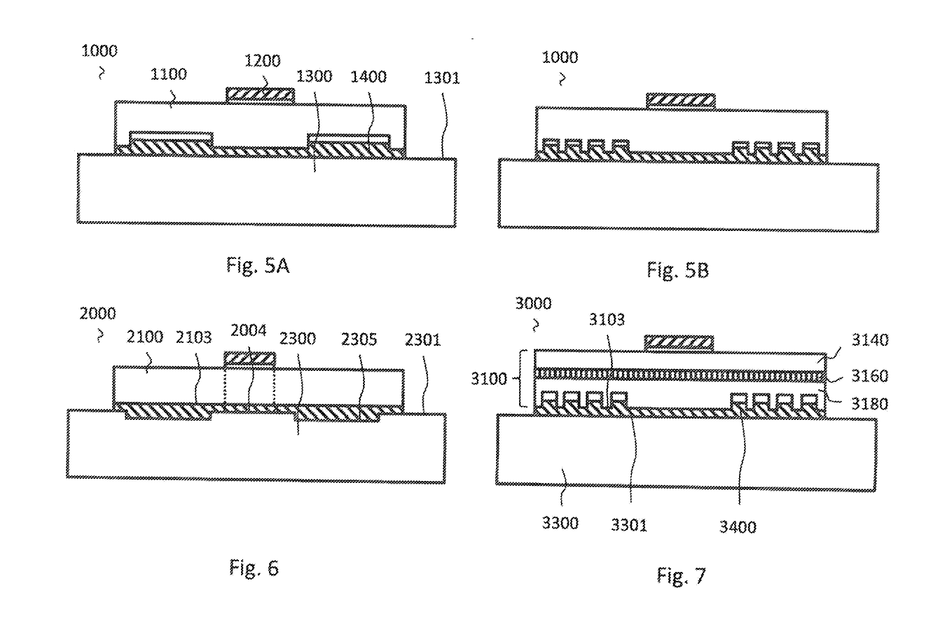

FIGS. 5A and 5B show a semiconductor module 1000 that may comprise a carrier 1100, a semiconductor chip 1200, a heatsink 1300 and a thermal grease layer 1400. Semiconductor module 1000 may further comprise an encapsulant (not shown) that may at least partially encapsulate the semiconductor chip 1200. Carrier 1100 may be similar to any of the carriers 100, 200, 300 and 400.

Thermal grease layer 1400 may be configured such that heat may flow from carrier 1100 to heatsink 1300. Thermal grease layer 1400 may have a minimum thickness in the range of about 30 μm (micrometer) to about 5 mm. In particular, the regions below any thermal hotspot may exhibit such a minimum thickness of the thermal grease layer.

In FIG. 6 a further semiconductor module 2000 in accordance with the disclosure is shown. Semiconductor module 2000 may be identical to semiconductor module 1000 except for the fact that in semiconductor module 2000 it may be a first surface 2301 of heatsink 2300 instead of backside 2103 of carrier 2100 that may have a surface structure 2305 in the form of trenches and/or dimples. Surface structure 2305 may be configured to act as a reservoir for excess thermal grease. Trenches and/or dimples 2305 on first heatsink surface 2301 may be fabricated using similar surface structuring techniques and may have similar dimensions and a similar alignment with respect to an area 2004 below a semiconductor chip (or any other thermal hotspot) as trenches 105 and dimples 205 of carriers 100, 200, 300 and 400.

FIG. 7 shows a further semiconductor module 3000 in accordance with the disclosure. Semiconductor module 3000 may comprise a carrier 3100 comprising trenches and/or dimples on carrier backside 3103. Alternatively, semiconductor module 3000 may comprise trenches and/or dimples on first heatsink surface 3301 similar to semiconductor module 2000.

A difference between semiconductor module 3000 and previously described semiconductor modules 1000, 2000 may be that semiconductor module 3000 may comprise a base plate 3180, whereas semiconductor modules 1000, 2000 may not necessarily comprise such base plate. Carrier 3100 of semiconductor module 3000 may comprise a first substrate layer 3140 that may be similar to carriers 100, 200, 300, 400 except that it may not necessarily comprise trenches 105 or dimples 205. First substrate layer 3140 may be coupled to a second substrate layer 3180 via a coupling layer 3160 that may comprise a solder bond. Second substrate layer 3180 may comprise a base plate. Base plate 3180 may be coupled to heatsink 3300 with a thermal grease layer 3400 arranged in between.

In one example, semiconductor modules 1000, 2000 and 3000 may correspond to power semiconductor modules. In further examples, semiconductor modules 1000, 2000 and 3000 may also be any other type of semiconductor module.

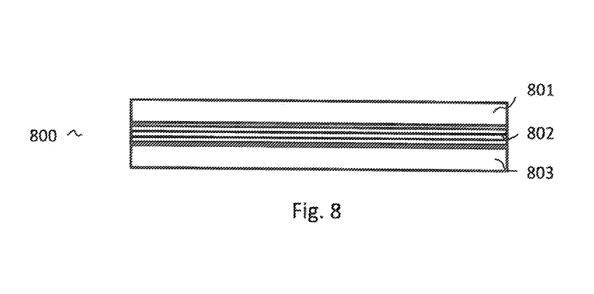

In FIG. 8 a side view of an exemplary DCB substrate 800 is shown. DCB substrate 800 may comprise a first metallic layer 801, a ceramics layer 802 and a second metallic layer 803. For example, a DCB substrate like DCB substrate 800 may be comprised in carriers 100, 200, 300 and 400.

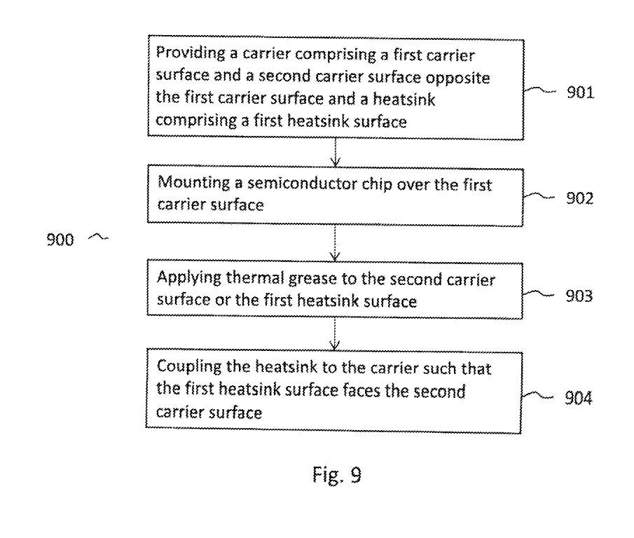

In FIG. 9 a flow diagram of a method 900 for fabricating a semiconductor module is shown. Method 900 may comprise a first act 901 of providing a carrier comprising a first carrier surface and a second carrier surface opposite the first carrier surface and a heatsink comprising a first heatsink surface. Method 900 may comprise a second act 902 of mounting a semiconductor chip over the first carrier surface. Method 900 may comprise a third act 903 of applying thermal grease to the second carrier surface or the first heatsink surface. Method 900 may comprise a fourth act 904 of coupling the heatsink to the carrier such that the first heatsink surface faces the second carrier surface. According to method 900 one of the second carrier surface and the first heatsink surface comprises a surface structuring. The surface structuring may be provided in form of trenches and/or dimples as e.g. described in connection with foregoing examples.

Applying the thermal grease to the second carrier surface or the first heatsink surface may be done using any method for applying thermal grease. For example, applying thermal grease may comprise using an inkjet and/or a squeegee. Note that according to method 900 the thermal grease may be applied in such a way that trenches and/or dimples configured to act as reservoirs for excess thermal grease may be kept free or mostly free of thermal grease.

The trenches and/or dimples may be configured to support a distribution of the thermal grease over the second carrier surface and the first heatsink surface. For example, the thermal grease may be applied in form of a droplet in the center of the second carrier surface or the first heatsink surface and the trenches and/or dimples may support a flow of the thermal grease out of the center.

According to an embodiment of a method for fabricating a semiconductor module the thermal grease may be only applied to that one surface of the second carrier surface and the first heatsink surface which does not comprise trenches 105 or dimples 205 configured to act as reservoirs for excess thermal grease. When coupling the heatsink to the second carrier surface a pressure may be applied and excess thermal grease may be pressed into the trenches and/or dimples such that at least a part of the trenches and/or dimples may be at least partially filled with thermal grease.

Coupling the heatsink to the second carrier surface may comprise using a fixing means to create a mechanical coupling between the carrier and the heatsink. The fixing means may for example comprise a clamp, a screw and/or a spring as well as any other suitable fixing means. The coupling means may be arranged on the periphery of the carrier. For example, several clamps, screws and/or springs may be arranged along the edge of the carrier.

Although the present invention and its advantages have been described in detail, it should be understood that various changes, substitutions and alterations can be made herein without departing from the spirit and scope of the disclosure as defined by the appended claims.

It is possible to combine features of the disclosed devices and methods unless specifically stated otherwise.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A carrier, comprising:
a first surface comprising at least a first semiconductor chip bearing area; and
a second surface opposite the first surface and comprising at least one cavity in the form of one or more of dimples and trenches.

2. The carrier of claim 1, wherein the carrier comprises a ceramic.

3. The carrier of claim 1, wherein the carrier comprises a direct copper bond substrate.

4. A semiconductor module, comprising:
a carrier comprising a first carrier surface and a second carrier surface opposite the first carrier surface;
a first semiconductor chip mounted over the first carrier surface; and
a heatsink coupled to the second carrier surface with a first heatsink surface facing the carrier;
wherein the second carrier surface or the first heatsink surface comprises at least one cavity in the form of one or more of dimples and trenches.

5. The semiconductor module of claim 4, wherein the first semiconductor chip is a power semiconductor chip.

6. The semiconductor module of claim 4, further comprising a second semiconductor chip mounted over the first carrier surface.

7. The semiconductor module of claim 6, wherein the second semiconductor chip is an integrated circuit chip.

8. The semiconductor module of claim 4, further comprising an encapsulation at least partially encapsulating the first semiconductor chip.

9. The semiconductor module of claim 4, wherein the semiconductor module is a power module without a base plate.

10. The semiconductor module of claim 4, wherein the semiconductor module is a power module comprising a base plate, wherein the heatsink is coupled to the second carrier surface via the base plate.

11. The semiconductor module of claim 4, further comprising a thermal grease located between the carrier and the heatsink and at least partially filling the at least one cavity.

12. The semiconductor module of claim 4, further comprising a fixing means for mechanically fixing the heatsink to the carrier.

13. The semiconductor module of claim 4, wherein an area of the second carrier surface below one or more of a semiconductor chip and an electrical contact located over the first carrier surface is free of the at least one cavity.

14. The semiconductor module of claim 4, wherein a first area of the second carrier surface defined by an outline of the first semiconductor chip is free of the at least one cavity.

15. The semiconductor module of claim 14, wherein a second area of the second carrier surface directly adjacent to the first area is free of the at least one cavity.

16. The semiconductor module of claim 14, wherein the trenches are oriented perpendicular or radial with respect to an outline of the first area.

17. A method for fabricating a semiconductor module, the method comprising:
providing a carrier comprising a first carrier surface and a second carrier surface opposite the first carrier surface;
mounting a first semiconductor chip over the first carrier surface; and
coupling a heatsink to the second carrier surface such that a first heatsink surface faces the second carrier surface;
wherein the second carrier surface or the first heatsink surface comprises at least one cavity in the form of one or more of dimples and trenches.

18. The method of claim 17, wherein the at least one cavity is formed by etching the second carrier surface or the first heatsink surface.

19. The method of claim 17, further comprising applying a thermal grease to the second carrier surface or the first heatsink surface, wherein applying the thermal grease comprises using a squeegee.

20. The method of one claim 17, wherein coupling the heatsink to the second carrier surface comprises applying pressure such that a thermal grease applied to the second carrier surface or the first heat sink surface at least partially fills the at least one cavity.
